(19) United States
(12) Patent Application Publication
(10) Pub. No.: US 2026/0045765 A1
(43) Pub. Date: Feb. 12, 2026

(54) Method for Initializing a Laser System

(71) Applicant: Robert Bosch GmbH, Stuttgart (DE)

(72) Inventors: Joern Hoffarth, Reutlingen (DE); David Copeto, Ludwigsburg (DE); Stefan Noe, Stuttgart (DE)

(21) Appl. No.: 19/290,609

(22) Filed: Aug. 5, 2025

(30) Foreign Application Priority Data
Aug. 7, 2024 (DE) 10 2024 207 469.1

(51) Int. Cl. H01S 5/042

(52) U.S. Cl. CPC H01S 5/042

(57) ABSTRACT

A method for initializing a laser system includes (i) reading a value of an integral part of a laser control signal of the laser system before switching off the laser system, (ii) switching off the laser system, and (iii) initializing the laser system upon restarting with the read value, wherein the read value in an initialization register is used for the integral part of the laser control signal. A computer program, an apparatus, and a storage medium for this purpose is also disclosed.

This application claims priority under 35 U.S.C. § 119 to application no. DE 10 2024 207 469.1, filed on Aug. 7, 2024 in Germany, the disclosure of which is incorporated herein by reference in its entirety.

The disclosure relates to a method for initializing a laser system. The disclosure further relates to a computer program, an apparatus, and a storage medium for this purpose.

### BACKGROUND

Quickly achieving the rated power of a laser system at startup is of primary importance for numerous applications requiring precise and efficient laser technology. Ramp-up delays can result in significant efficiency losses, increased operating costs, and possible quality degradation. A laser system that rapidly reaches its rated power minimizes downtime and enables immediate readiness for use.

In order to be able to use the maximum permissible laser power, it is particularly necessary to control it precisely without overshoots. After switching it on, it may take a few milliseconds for the laser power to reach its rated power and for the measurement procedure to start. The output voltage at which the rated power is reached is dependent on temperature and component tolerances, so that uniform adjustment is not possible during production.

### SUMMARY

The subject matter of the disclosure is a method, a computer program, a device, and a computer-readable storage medium having the features set forth below. Further features and details of the disclosure will emerge from the description and the drawings. Features and details which are described in connection with the method according to the disclosure naturally also apply in connection with the computer program according to the disclosure, the apparatus according to the disclosure, and the computer-readable storage medium according to the disclosure, and vice versa in each case, so that a reciprocal reference is always possible with regard to the disclosure of the disclosure.

The subject matter of the disclosure is in particular a method for initializing a laser system, comprising the following steps, wherein the steps can be repeated and/or performed in a certain order. In particular, the laser system is a laser rangefinder. Thus, the method according to the disclosure is particularly relevant for applications where exact distance measurement is critical. By achieving the rated power faster and with improved initialization of the laser system, the measurements can be more precise and efficient.

In a first step, a value of an integral part of a laser control signal of the laser system is preferably read before switching off the laser system. To read the value of the integral part, an output signal of a measurement controller can be tapped into. This signal may then be converted into a digital format and captured by a microcontroller. The current integral value is preferably already in digital form. It may be useful to play back a reduced value of, for example, 90% in order to avoid overshooting. Alternatively, the value of the integral part may be calculated by applying a corresponding mathematical formula that indicates the value of the integral of the controller output signal over time. A complex mathematical formula would be conceivable, taking into account a temperature and pause time.

In a further step, the laser system is preferably switched off.

In a further step, the laser system is preferably initialized with the read value upon restarting, wherein the read value in an initialization register is used for the integral part of the laser control signal. The initialization register may be a memory area that is can be used for configuration and setting initial conditions of the laser system when switching it on or starting.

By using the initialization register according to the disclosure, it can be ensured that the laser system can ramp up quickly and reliably to a desired rated power. Thus, advantageously, the start-up time of the laser system can be significantly reduced. By initializing the integral part of the laser control signal with the previously read value, the laser can thus increase to its rated power more quickly. This in particular enables faster performance of the actual measurement and thus more efficient use of the laser system.

Furthermore, it may be contemplated that initializing the laser system further comprises the step of:
checking the laser control signal based on at least one stability indicator, wherein the at least one stability indicator evaluates a stability of a laser power of the laser system based on a specified range of values.

This in particular ensures that the stability of the laser power is assessed prior to the start of measurement. A microcontroller of the laser system may decide whether the laser system is ready for reliable measurement based on the stability indicator. This may increase accuracy of subsequently acquired measurement data and may prevent or at least reduce erroneous measurements.

A further advantage in the context of the disclosure can be achieved if the initialization of the laser system further comprises the following step:
canceling the start-up, i.e. particularly restarting, if a result of the check indicates a low stability, wherein the low stability is determined based on the specified range of values of the at least one stability indicator.

In this way, it is possible that an erroneous behavior of the laser system is detected and prevented. Low stability detection allows for early intervention and thus prevents potentially harmful effects on the measurement accuracy or the laser system itself.

According to a further possibility, it can be contemplated that the initialization of the laser system further comprises the following step:
starting a measurement operation of the laser system, if a result of the check indicates sufficiently high stability, wherein the sufficiently high stability is determined based on the specified range of values of the at least one stability indicator.

It is thus possible that the measurement operation is only started after a check of the stability indicator. This step can ensure that the laser is running in a stable condition and more reliable subsequent measurement is guaranteed.

It is further contemplated that the at least one stability indicator provides an allowable range for the integral part of the laser control signal and/or an allowable range for the laser power. Alternatively, in particular based on two differently-sized number ranges, a control deviation from a target value can be specified by the stability indicator. It is thus possible that a defined range of values is defined for the integral part of the laser control signal and/or the laser power. This range of values is particularly used as a reference. With this specified range of values, a microcontroller can precisely assess, for example, whether the laser power is within acceptable limits when initializing the laser system. Such a specified range of values may allow for more reliable initialization of the laser system and may reduce a likelihood of instabilities during the measurement run.

Another object of the disclosure is a computer program, in particular a computer program product, comprising commands which, when the computer program is executed by a computer, cause the computer to carry out the method according to the disclosure. The computer program according to the disclosure thus brings with it the same advantages as have been described in detail with reference to a method according to the disclosure.

The disclosure also relates to an apparatus for data processing which is configured so as to carry out the method according to the disclosure. The apparatus can be a computer, for example, that executes the computer program according to the disclosure. The computer can comprise at least one processor for executing the computer program. A non-volatile data memory can be provided as well, in which the computer program can be stored and from which the computer program can be read by the processor for execution. The device may also be an analog discrete electronic circuit or an integrated electronic circuit configured to perform the method according to the disclosure.

The disclosure can also relate to a computer-readable storage medium, which comprises the computer program according to the disclosure and/or commands that, when executed by a computer, prompt said computer program to carry out the method according to the disclosure. The storage medium is configured as a data memory such as a hard drive and/or a non-volatile memory and/or a memory card, for example. The storage medium can, for example, be integrated into the computer.

In addition, the method according to the disclosure can also be designed as a computer-implemented method. Alternatively or additionally, at least one of the disclosed method steps may be computer-implemented and/or performed automatically.

### BRIEF DESCRIPTION OF THE DRAWINGS

Further advantages, features, and details of the disclosure emerge from the following description, in which exemplary embodiments of the disclosure are described in detail with reference to the drawings. The features mentioned in the claims and in the description can each be essential to the disclosure individually or in any combination. The figures show:

FIG. 1 a schematic visualization of a method, a device, a storage medium, and a computer program according to exemplary embodiments of the disclosure,

FIG. 2 a schematic illustration of a laser system according to exemplary embodiments of the disclosure.

### DETAILED DESCRIPTION

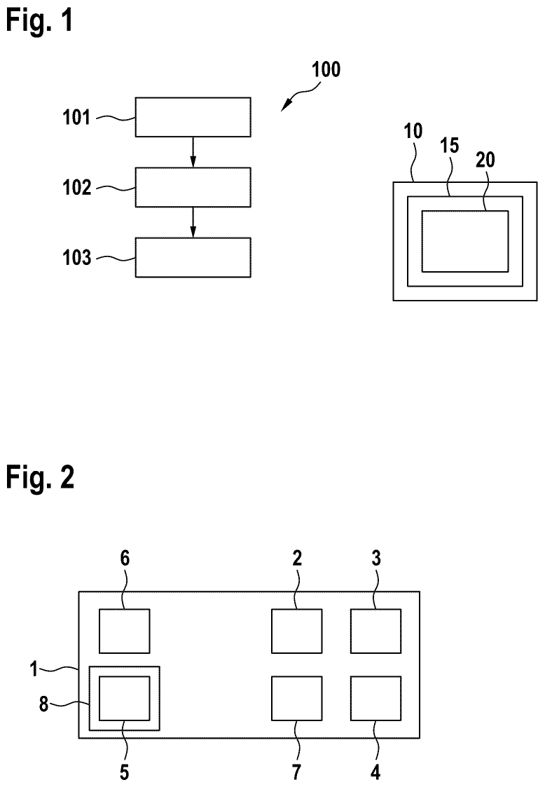

FIG. 1 schematically illustrates a method 100, a device 10, a storage medium 15, and a computer program 20 according to exemplary embodiments of the disclosure.

In particular, FIG. 1 shows an exemplary embodiment of a method 100 for initializing a laser system 1. In a first step 101, a value of an integral part of a laser control signal of the laser system 1 is read before switching off the laser system 1. In a second step 102, the laser system 1 is switched off. In a third step 103, the laser system 1 is initialized with the read value upon restarting, wherein the read value in an initialization register 6 is used for the integral part of the laser control signal for this purpose.

The method of the present disclosure relates to a laser system 1, and according to exemplary embodiments, in particular to a laser rangefinder that uses the indirect Time of Flight (iToF) measurement method. For this exemplary embodiment, reference is made to FIG. 2. For example, this laser rangefinder 1 operates by measuring a phase shift of a modulated light signal emitted by the laser rangefinder and reflected by a target object. The following is a description of how the Indirect Time of Flight (iToF) measurement works. First, a laser 3, in particular a laser diode of the laser 3, can transmit intensity-modulated light in the laser rangefinder 1, for example in the infrared or visible area, towards a target object. The modulation is in particular carried out with a sinusoidal or square wave. The intensity-modulated light subsequently strikes the target object and is reflected back to the laser rangefinder 1. A detector 4 in the measuring device can now receive the reflected light. Since the light takes a certain amount of time to travel the distance, there is a phase shift between the transmitted signal and the received signal. This phase shift between the transmitted signal and the received signal may then be measured. This phase shift is in particular proportional to the distance of the light traveled. The distance may then be calculated from the phase shift taking into account the wavelength of the modulation and the speed of light. It may further be provided that a reference phase is determined with a second detector having a constant distance (not shown) to determine the phase shift based on a comparison to the reference phase.

The laser rangefinder 1 may comprise a measurement controller 2. The measurement controller 2 in particular assumes the laser control function, i.e., for example, a control system of the laser 3.

Thus, the measurement controller 2 may control an emission of the laser 3 by controlling switching the power on and off, as well as controlling intensity and modulation of a laser beam of the laser 3. This can ensure that the laser beam is transmitted at the correct power and with the correct characteristics.

Furthermore, a laser beam of the laser system 1 may be modulated, for example in the form of pulsed light and/or a continuous wave of variable modulation frequency. Upon receipt by the detector 4 of at least a fraction of the transmitted laser light, the measurement controller 2 may process the received signal. This includes, for example, amplification, filtering and conversion of the received analog signal into a digital signal for further analysis, in particular by an analog-digital converter 5. Furthermore, the phase shift between the transmitted signal and the received signal may be measured and optionally compared to the reference phase.

The measurement controller 2 may also periodically perform calibrations to ensure that the measurements are precise. For this purpose, it can monitor a state of the laser 3 and the detector 4 to ensure that they are functioning properly.

In addition, the laser system 1, in particular the laser rangefinder, can comprise an analog-digital converter 5. The analog-digital converter 5 preferably converts analog signals received from the detector 4 into digital signals. In particular, these signals represent an intensity of light transmitted by the laser 3 and sent back from the target object. The digital conversion may allow the phase shift between the transmitted signal and the received signal to be analyzed. The digital signals provided by the respective analog-digital converter 5 may be further filtered, amplified, and processed to reduce noise and improve signal quality.

In addition, the laser system 1 can comprise an application-specific integrated circuit 8 in which, for example, the analog-digital converter 5 can be located. The laser system 1 can also comprise a microcontroller 7 in order to carry out laser control functions with the microcontroller 7. Furthermore, the laser system 1 can have at least one initialization register 6 in order to store data therein, for example the value of the integral part of the laser control signal.

With the method according to exemplary embodiments, a laser rated power can advantageously be achieved more quickly and an actual measurement can thus be started more quickly.

Before switching off the laser 3, a value of an integral part is preferably read and stored in the initialization register 6 of the integral part at the next start-up. By way of stability indicators (e.g., characterized by “laser ok” and “laser unstable”), a microcontroller 7 of the laser system 1 preferably checks the laser control signal at start-up. Based on the result, the microcontroller 7 in particular cancels the start or can directly initiate a start of the measurement.

The above explanation of the embodiments describes the present disclosure solely within the scope of examples. Of course, individual features of the embodiments can be freely combined with one another, if technically feasible, without leaving the scope of the present disclosure.

What is claimed is:

1. A method for initializing a laser system, comprising:
reading a value of an integral part of a laser control signal of the laser system before switching off the laser system;
switching off the laser system; and
initializing the laser system upon restarting with the read value, wherein the read value in an initialization register is used for the integral part of the laser control signal.

2. The method according to claim 1, wherein the initializing the laser system further comprises:
checking the laser control signal based on at least one stability indicator, wherein the at least one stability indicator evaluates a stability of a laser power of the laser system based on a specified range of values.

3. The method according to claim 2, wherein the initializing the laser system further comprises:
canceling the start-up if a result of the check indicates a low stability, wherein the low stability is determined based on the specified range of values of the at least one stability indicator.

4. The method according to claim 2, wherein the initializing the laser system further comprises:
starting a measurement operation of the laser system, if a result of the check indicates sufficiently high stability, wherein the sufficiently high stability is determined based on the specified range of values of the at least one stability indicator.

5. The method according to claim 2, wherein the at least one stability indicator specifies an allowable range for the integral part of the laser control signal and/or an allowable range for the laser power.

6. The method according to claim 1, wherein the laser system is a laser rangefinder.

7. A computer program, comprising instructions that, when the computer program is executed by a computer, cause the computer to carry out the method according to claim 1.

8. A device for data processing, configured to carry out the method according to claim 1.

9. A computer-readable storage medium, comprising instructions which, when executed by a computer, cause said computer to carry out the steps of the method according to claim 1.
